(19) United States
(12) Patent Application Publication
(10) Pub. No.: US 2008/0191365 A1
(43) Pub. Date: Aug. 14, 2008

(54) Optical semiconductor device

(75) Inventors: Makoto Ueda, Yamanasahi (JP); Syu Goto, Yamanasahi (JP); Shigekazu Izumi, Yamanasahi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Nakakoma-gun (JP)

(21) Appl. No.: 12/068,693

(22) Filed: Feb. 11, 2008

(30) Foreign Application Priority Data
Feb. 9, 2007 (JP) 2007-030570

(51) Int. Cl. H01L 23/48

(52) U.S. Cl. 257/778; 257/E23.023

(57) ABSTRACT

An optical semiconductor device includes a first electrode joined to a first joining face of a mounting portion that is provided in one of a main surface and a back surface of a semiconductor chip, and a second electrode joined to a second joining face of the mounting portion that is provided in one of the main and back surfaces and a side surface of the semiconductor chip, the second joining face crossing the first joining face.

### BACKGROUND OF THE INVENTION

1. Field of the Invention

The present invention generally relates to optical semiconductor devices, and more particularly, to an optical semiconductor device that inputs and outputs electrical signals from a sidewall of a semiconductor chip.

2. Description of the Related Art

There is known an optical semiconductor device in which a semiconductor chip is mounted on a mount portion, which may be a package, a mounting substrate, or a tool. Japanese Patent Application Publication No. 2001-135891 discloses an optical semiconductor device with a semiconductor laser chip being mounted on a sub-mount. The above publication shows the following in FIG. 1. The semiconductor laser chip is mounted on the sub-mount in such a manner that the main or front surface of the semiconductor laser chip faces down. The main surface is located on the side of the semiconductor laser chip on which an operating layer composed of a clad layer and an active layer is located. Ohmic electrodes are provided on the main surface of the semiconductor laser chip and are electrically connected to the sub-mount. Ohmic electrodes are also provided on the back surface of the semiconductor laser chip (on which a semiconductor substrate is provided), and bonding wires are bonded thereto.

The prior art disclosed in the above publication may need image recognition in order to improve the accuracy of alignment of the semiconductor chip with the mounting portion. The alignment with image recognition increases the manufacturing cost. The alignment accuracy is restricted due to the precision of image recognition. Particularly, the semiconductor laser chip is required to be aligned with an accuracy of a few μm. There is a demand for a highly accurate simple alignment method without image recognition.

Electrical signals are input and output via the main and back surfaces of the semiconductor laser chip. One of the main and back surfaces is mounted on the sub-mount and the other is wire-bonded. Thus, bonding wires are bonded to either the main or back surface of the semiconductor laser chip. In this bonding process, the active layer of the semiconductor laser chip may be damaged.

### SUMMARY OF THE INVENTION

The present invention has been made in view of the above circumstances and provides an optical semiconductor device in which a semiconductor chip is accurately aligned with a mounting portion.

According to an aspect of the present invention, there is provided an optical semiconductor device including: a first electrode joined to a first joining face of a mounting portion that is provided in one of a main surface and a back surface of a semiconductor chip; and a second electrode joined to a second joining face of the mounting portion that is provided in one of the main and back surfaces and a side surface of the semiconductor chip, the second joining face crossing the first joining face.

According to another aspect of the present invention, there is provided an optical semiconductor device including: a semiconductor chip; a first electrode provided on at least one of a main surface and a back surface of the semiconductor chip; a second electrode provided on any of the main and back surfaces and a side surface of the semiconductor chip; a mounting portion on which the semiconductor chip is mounted; a first joining face which is joined to the first electrode and is provided on the mounting portion; and a second joining face which is joined to the second electrode and is provided on the side surface of the mounting portion crossing the first joining face.

### BRIEF DESCRIPTION OF THE DRAWINGS

FIGS. 1A through 1D are cross-sectional views of steps of a process for fabricating an optical semiconductor device in accordance with a first embodiment;

FIGS. 2A through 2C are perspective views (No. 1) of steps of the process for fabricating the optical semiconductor device in accordance with the first embodiment;

FIGS. 3A and 3B are perspective views (No. 2) of steps of the process for fabricating the optical semiconductor device in accordance with the first embodiment;

FIG. 4 is a perspective view (No. 3) of steps of the process for fabricating the optical semiconductor device in accordance with the first embodiment;

FIG. 5 is a perspective view (No. 4) of steps of the process for fabricating the optical semiconductor device in accordance with the first embodiment;

FIGS. 6A and 6B are perspective views of steps of a process for fabricating an optical semiconductor device in accordance with a second embodiment;

FIGS. 7A and 7B are perspective views of steps of a process for fabricating an optical semiconductor device in accordance with a first variation of the second embodiment;

FIGS. 8A and 8B are perspective views of steps of a process for fabricating an optical semiconductor device in accordance with a second variation of the second embodiment;

FIGS. 9A and 9B are perspective views of a sub-mount and an optical semiconductor device in accordance with a third embodiment;

FIGS. 10A and 10B are perspective views of a sub-mount and an optical semiconductor device in accordance with a fourth embodiment;

FIGS. 11A and 11B are perspective views of a sub-mount and a substrate in accordance with a fifth embodiment;

FIG. 12 is a perspective view of an optical semiconductor device in accordance with the fifth embodiment;

FIGS. 13A and 13B are perspective views of a sub-mount and an optical semiconductor device in accordance with a sixth embodiment;

FIG. 14 is a perspective view of an optical semiconductor device in accordance with a seventh embodiment;

FIG. 15 is a perspective view of an optical semiconductor device in accordance with an eighth embodiment; and

FIG. 16 is a perspective view of an optical semiconductor device in accordance with a ninth embodiment

### DESCRIPTION OF THE PREFERRED EMBODIMENTS

A description will now be given of embodiments of the present invention with reference to the accompanying drawings.

### First Embodiment

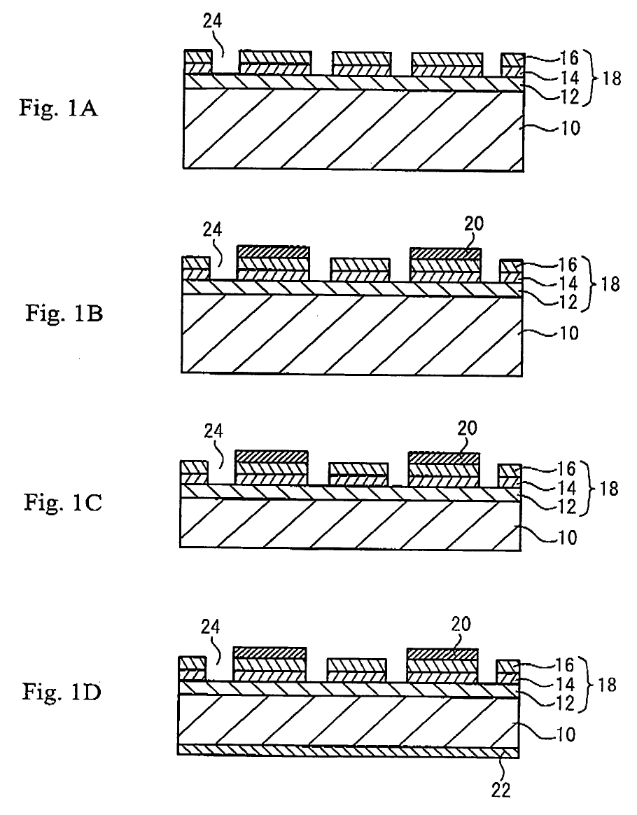

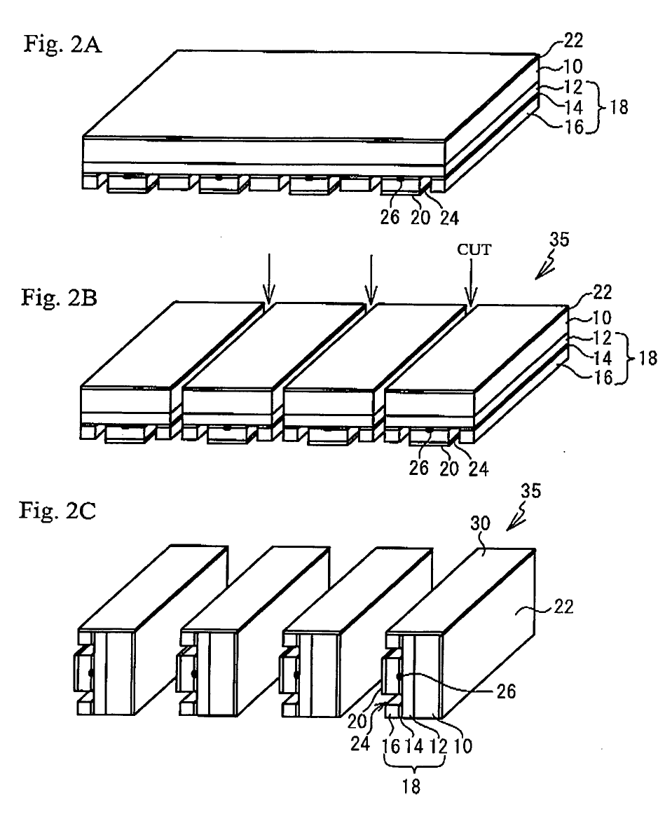

A description will be given, with reference to FIGS. 1A through 5, of an optical semiconductor device in accordance with a first embodiment. FIGS. 1A through 1D are respectively schematic cross-sectional views showing steps of a method for fabricating a semiconductor laser chip. Referring to FIG. 1A, an operating layer 18 is formed on an n-type GaAs substrate 10 doped with Si (silicon) by MOCVD (Metal Organic Chemical Vapor Deposition). The operating layer 18 is composed of an n-type second clad layer 12 of AlGaInP (aluminum gallium indium phosphide), an active layer 14 of MQW (Multi Quantum Well) of InGaP/AlGaInP, and a p-type first clad layer 16 of AlGaInP doped with Zn (zinc). Grooves 24 are formed in the operating layer 18 so that the first clad layer 16 and the active layer 14 are removed. The center portions of the divided portions of the active layer 14 are respective light-emitting regions 26 (see FIG. 2A and subsequent figures).

As shown in FIG. 1B, first electrodes 20 made of Au or the like are formed on the first clad layer 16 in a part of the main or front surface of the substrate 10 (on which the operating layer 18 is provided) by evaporation or plating. As shown in FIG. 1C, the backside of the substrate 10 is grinded to thin the substrate 10. As shown in FIG. 1D, a third electrode 22 made of, for example, Au is formed on the entire backside of the substrate 10 by evaporation or plating.

FIG. 2A is a perspective view of the layer structure shown in FIG. 1D, in which the main surface of the substrate 10 faces down. Multiple semiconductor laser chips are integrally arranged side by side. Referring to FIG. 2B, the substrate 10 is divided into semiconductor laser chips 35 by an appropriate method, which may be a laser dividing method, a dicing method or a scribing method. Referring to FIG. 2C, the semiconductor laser chips 35 are arranged so that side surfaces thereof face up. Then, second electrodes 30 made of, for example, Au (gold) are formed on the side surfaces of the semiconductor laser chips 35 by evaporation or plating.

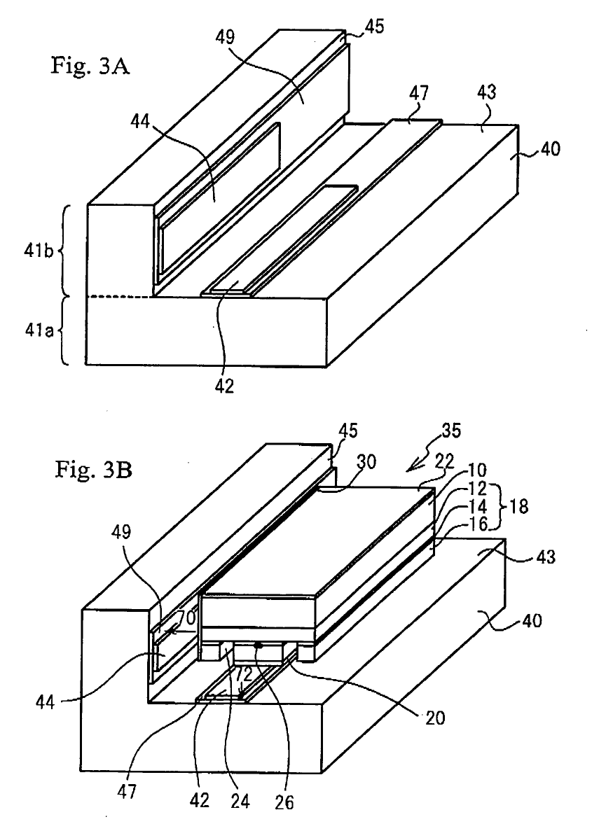

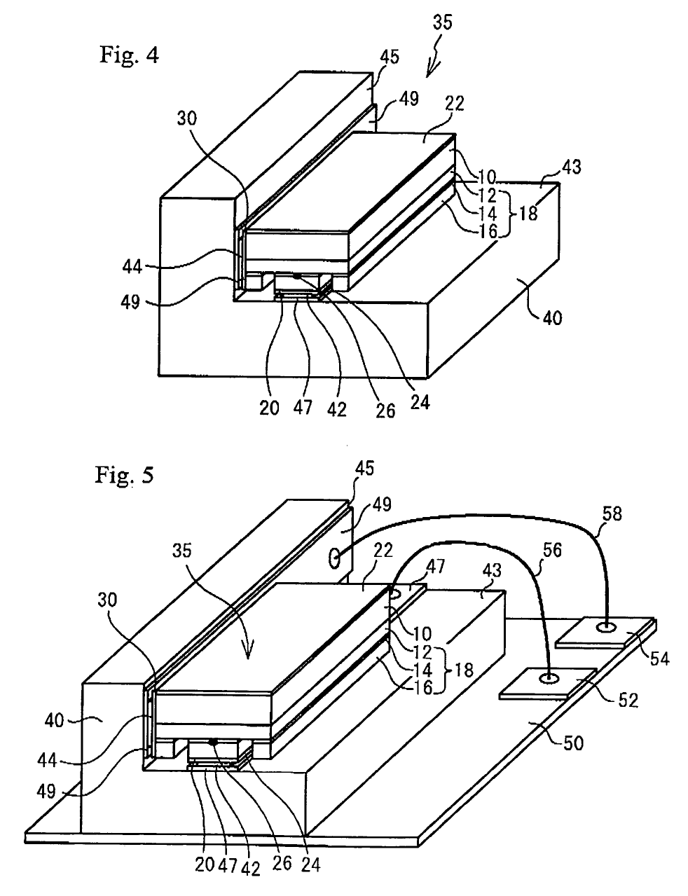

FIG. 3A is a perspective view of a part of a sub-mount 40 (mounting portion) on which the semiconductor laser chip 35 is mounted. The sub-mount 40 is made of an insulating material such as ceramic. The sub-mount 40 has an L shape viewed from the front thereof, and is composed of a base 41a and a protrusion 41b. The upper surface of the base 41a is a first joining face 43, to which the first electrode 20 of the semiconductor laser chip 35 is joined. An electrode 47 made of, for example, Au is provided on the first joining face 43. A brazing member 42, which is made of, for example, Pb (lead), AuSn (gold-tin) or solder, is provided on the electrode 47. The inner surface of the protrusion 41b is a second joining face 45 to which the second electrode 30 of the semiconductor laser chip 35 is joined. An electrode 49 made of, for example, Au is provided on the second joining face 45. A brazing member 44, which made of, for example, Pb, AuSn or solder, is provided on the electrode 49. The first joining face 43 is provided on the flat surface of the sub-mount 40 (the upper surface of the base 41a), and the second joining face 45 is provided on the side surface of the sub-mount (the inner surface of the protrusion 41b) that crosses the flat surface of the sub-mount 40.

Referring to FIG. 3B, the semiconductor laser chip 35 is brought into contact with the second joining face 45, as indicated by an arrow 70. Thus, the lateral mount position of the semiconductor laser chip 35 is defined. The semiconductor laser chip 35 is brought into contact with the first joining face 43, as indicated by an arrow 72. Preferably, the angle formed by the first joining face 43 and the second joining face 45 is approximately equal to the angle formed by the main surface and the side surface of the semiconductor laser chip 35. This relationship makes the first electrode 20 and the first joining face 43 parallel to each other. In this arrangement, the first electrode 20 is joined to the first joining face 43, so that the light-emitting region 26 can be positioned close to the sub-mount 40. It is thus possible to efficiently radiate heat generated in the light-emitting region 26 via the first joining face 43. As described above, the semiconductor laser chip 35 can be flip-chip bonded to the first joining face 43.

Referring to FIG. 4, the brazing member 42 and the first electrode 20 contact each other on the first joining face 43. The brazing member 44 and the second electrode 30 contact each other on the second joining face 45. As the temperature of the sub-mount 40 is raised, the brazing member 42 is melted, and the first electrode 20 is joined to the first joining face 43. Similarly, the brazing member 44 is melted, and the second electrode 30 is joined to the second joining face 45.

Referring to FIG. 5, the sub-mount 40 may be provided on a substrate So having an insulating substrate made of, for example, ceramic on which interconnection patterns are formed. Pads 52 and 54 are provided on the substrate 50. A bonding wire 56 is connected from the electrode 47 to the pad 52, and a bonding wire 58 is connected from the electrode 49 to the pad 54. Thus, the first electrode 20 of the semiconductor laser chip 35 is electrically connected to the pad 52, and the second electrode 30 is electrically connected to the pad 54. Through the above process, the optical semiconductor device of the first embodiment is completed.

The optical semiconductor device of the first embodiment has the first electrode 20 provided on the main surface of the semiconductor laser chip 35 (on the side on which the operating layer 18 is provided), and the second electrode 30 for inputting and outputting the electrical signals via the side surface of the semiconductor laser chip 35. The sub-mount 40 (mounting portion) has the electrode 47 that electrically joins the first electrode 20, and the electrode 49 that electrically joins the second electrode 30. That is, the semiconductor laser before being mounted on the sub-mount 40 has the first electrode 20 that is provided on the main surface of the semiconductor laser chip 35 and is joined to the first joining face 43 of the sub-mount 40, and the second electrode 30 that is provided on the side surface of the semiconductor laser chip 35 and is joined to the second joining face 45 provided on the sub-mount 40 crossing the first joining face 43.

According to the first embodiment, the electrical signals input to and output from the semiconductor laser chip 35 are routed in the front and side (vertical and lateral) directions of the semiconductor laser chip 35. The electrical signals input to and output from the semiconductor laser chip 35 in the lateral direction are connected to the third electrode 22 via the second electrode 30. Thus, there is no need for bonding wires on the semiconductor laser chip 35. It is thus possible to avoid damage in wire bonding to the semiconductor laser chip 35. The second electrode 30 and the second joining face 45 are joined together. Thus, as shown in FIG. 3B, the semiconductor laser chip 35 can be laterally positioned by the second joining face 45 when the semiconductor laser chip 35 is mounted on the sub-mount 40. This avoids image recognition for positioning of the semiconductor laser chip 35. According to the first embodiment, the semiconductor laser chip 35 can be easily positioned accurately.

As shown in FIG. 4, the optical semiconductor device of the first embodiment is manufactured by electrically joining the first electrode 20 provided on the lower surface of the semiconductor laser chip 35 and the electrode 47 provided on the first joining face 43 provided on the sub-mount 40, and electrically joining the second electrode 30 provided on the semiconductor laser chip 35 and the electrode 49 on the second joining face 45 provided on the sub-mount 40 for enabling input/output of the electrical signals from the side surface of the semiconductor laser chip 35. The step of joining the first electrode 20 to the first joining face 43 may be performed separate from the step of joining the second electrode 30 and the second joining face 45. Preferably, the two steps are simultaneously performed, as shown in FIG. 4.

As shown in FIG. 3B, at the time of mounting the semiconductor laser chip 35, the second electrode 30 is brought into contact with the second joining face 45, and thereafter, the first electrode 20 is brought into contact with the first joining face 43. Thus, the semiconductor laser chip 35 can be laterally positioned accurately.

### Second Embodiment

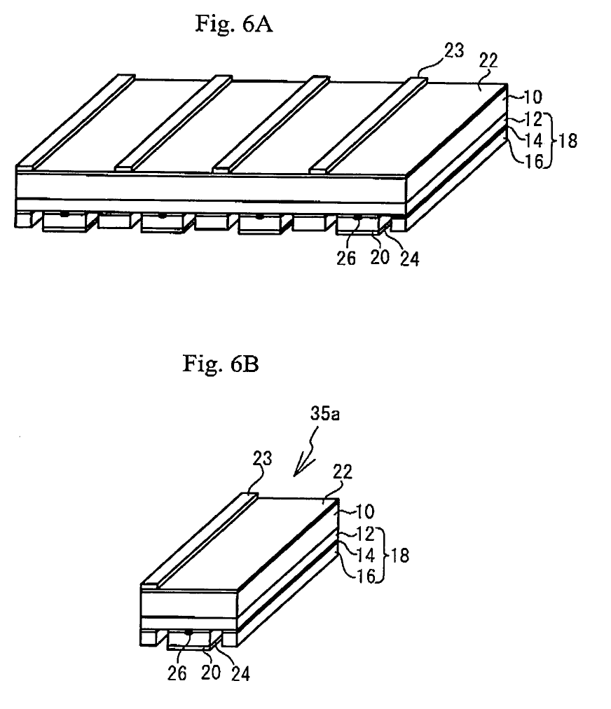

A second embodiment has an exemplary structure in which the second electrode is provided on either the main surface or the back surface of the semiconductor laser chip. FIG. 6A is a perspective view of a step of a process for fabricating an optical semiconductor device in accordance with the second embodiment. Second electrodes 23 are provided on the back surface of the semiconductor laser chip 35a in addition to the third electrode 22. The second electrodes 23 are made of, for example, Au, and are considerably thicker than the third electrode 22. The second electrodes 23 extend along the longitudinal sides of the semiconductor laser chips. The remaining structure of the second embodiment is the same as that of the first embodiment.

FIG. 6B is a perspective view of a semiconductor laser chip 35a obtained by cutting the substrate 10 shown in FIG. 6A. The semiconductor laser chip 35a does not have the second electrode on the side surface, which is different from the semiconductor laser chip 35 of the first embodiment. In the semiconductor laser chip 35a, the second electrode 23 that extends on the main surface along the side is thick enough to be joined to the brazing member 44 on the second joining face 45, as shown in FIG. 4.

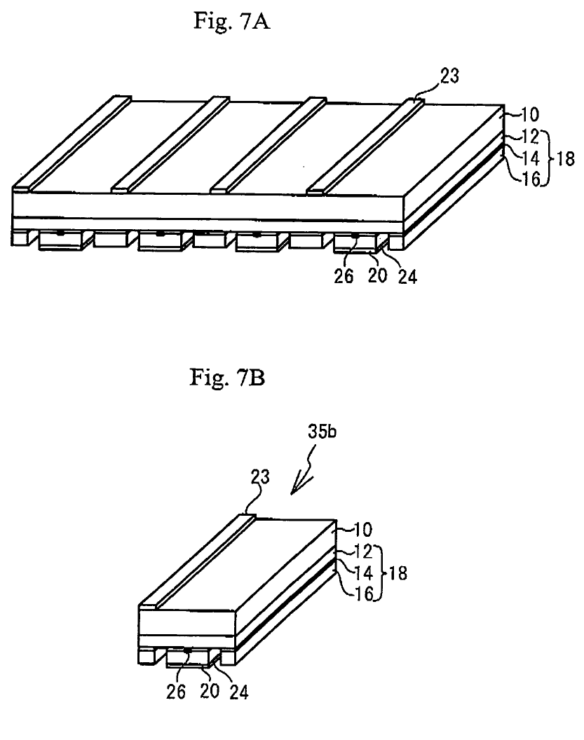

FIG. 7A is a perspective view of a step of a process for fabricating an optical semiconductor device in accordance with a first variation of the second embodiment. According to this variation, the third electrode 22 employed in the second embodiment shown in FIG. 6A is not provided on the back surface of a semiconductor laser chip 35b, and the second electrode 23 is provided directly on the substrate 10 along the side of the chip 35b. The remaining structure of the variation is the same as shown in FIG. 6A.

FIG. 7B is a perspective view of the semiconductor laser chip 35b obtained by cutting the substrate 10 shown in FIG. 7A. The second electrode is not provided on the side surface of the semiconductor laser chip 35b. In the semiconductor laser chip 35b, like the second embodiment, the second electrode 23 that extends on the back surface along the side is thick enough to be joined to the brazing member 44 on the second joining face 45, as shown in FIG. 4.

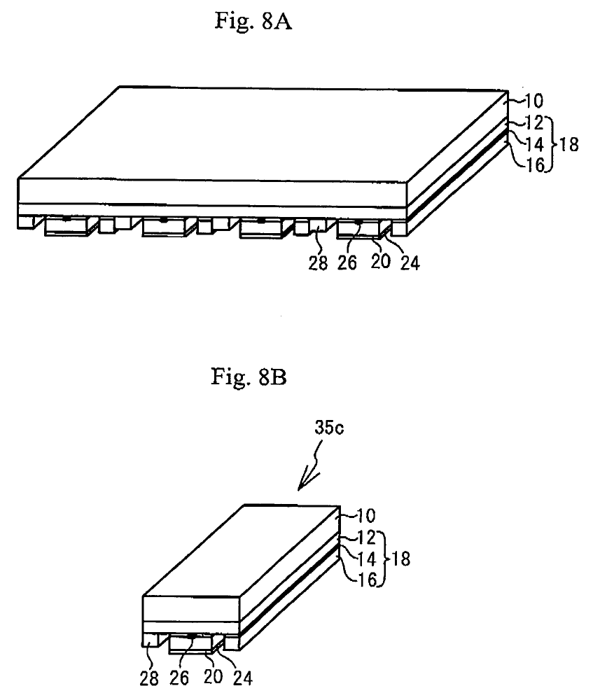

FIG. 8A is a perspective view of a step of a process for fabricating an optical semiconductor device in accordance with a second variation of the second embodiment. In the second variation, the third electrode 22 provided in the first embodiment is not provided on the back surface of the semiconductor laser chip 35c. The second electrode 28 is provided on the main surface of the semiconductor laser chip 35c so as to extend along the side opposite to the side along which the operating layer 18 extends. The second electrode 28 is electrically connected to the second clad layer 12. The remaining structure of the second variation is the same as that of the first embodiment shown in FIG. 2A.

FIG. 8B is a perspective view of one semiconductor laser chip 35c obtaining by cutting the substrate 10 shown in FIG. 8A. The second electrode is not provided on the side surface of the semiconductor laser chip 35c. The second electrode 28 that extends on the back surface along the side is thick enough to be joined to the brazing member 44 on the second joining face 45, as shown in FIG. 4.

The second embodiment and the two variations thereof do not have the second electrodes 30 provided on the side surfaces of the semiconductor laser chips 35a, 35b and 35c, but employ the second electrodes 23 or 28 provided on the back or main surfaces of the semiconductor laser chips 35a, 35b and 35c. It is thus possible to omit the steps of individually arranging the semiconductor laser chips 35 after the substrate 10 is cut as shown in FIG. 2C and then form the second electrodes 30 to the side surfaces of the semiconductor laser chips 35. Thus, the fabrication process can be simplified. As in the case of the first and second embodiments, the second electrode 30, 23 or 28 may be provided on any of the main, back or side surfaces of the semiconductor laser chip 35.

In the first and second variations of the second embodiment, the third electrode 22 or the second electrode 23 is not provided on the back surface of the semiconductor laser chip 35b or 35c. In other words, a metal film such as an electrode is not formed in a region in which the substrate 10 is divided into the semiconductor laser chip 35b or 35c. It is thus possible to easily divide the substrate 10 into the semiconductor chips 35b or 35c. In contrast, the second embodiment is configured so that the third electrode 22 is provided on the entire back surface of the semiconductor laser chip 35a, so that the electric field applied to the substrate 10 can be uniformed.

As in the case of the second embodiment and the two variations thereof, preferably, the second electrode 23 or 28 is provided on either the main or back surface of the semiconductor laser chip 35, and extends along one of the two opposite sides of the semiconductor laser chip 35. It is thus possible to reduce the time necessary to form the second electrode 23 provided along only one side of the semiconductor laser chip 35 by plating, as compared to the second electrode 23 provided on the entire back surface thereof. In addition, the thick metal film such as the second electrode 23 is not provided in the region in which the substrate 10 is divided into the semiconductor laser chips 35. It is thus easy to divide the substrate 10.

Preferably, the distance between the side surface of the semiconductor laser chip 35 and the side surface of the second electrode 23 or 28 is equal to or less than 3 μm. This limitation facilitates extension of the brazing member 44 up to the second electrode 23 or 28, so that the second electrode 23 or 28 and the second joining face 45 can be joined together more strongly.

The second embodiment and the variations thereof may be varied so that the second electrode 23 or 28 is buried in a groove formed in the main or back surface of any of the semiconductor laser chips 35a to 35c.

### Third Embodiment

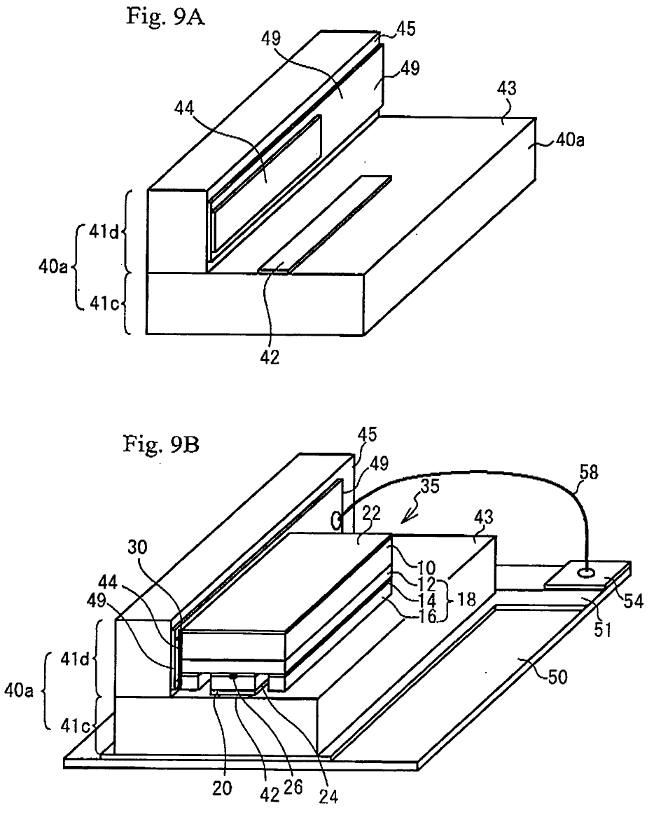

A third embodiment has a structure in which a part of the sub-mount is electrically conductive. FIG. 9A is a perspective view of a sub-mount in accordance with the third embodiment. Referring to FIG. 9A, a sub-mount 40a has a base 41c made of an electrically conductive material such as Cu (copper), and a protrusion 41d made of an insulating material such as ceramic. The brazing material 42 is directly provided on the base 41c. The electrode 49 and the brazing material 44 are provided to the protrusion 41d, as in the arrangement shown in FIG. 3. FIG. 9B is a perspective view of an optical semiconductor device in accordance with the third embodiment. The semiconductor laser chip 35 is mounted on the sub-mount 40a. In this state, the first electrode 20 is electrically connected to an interconnection line 51 on the substrate 50 via the base 41c. The second electrode 30 is connected to the pad 54 on the substrate 50 via the bonding wire 58. The remaining structure of the third embodiment is the same as shown in FIG. 5 showing the first embodiment.

### Fourth Embodiment

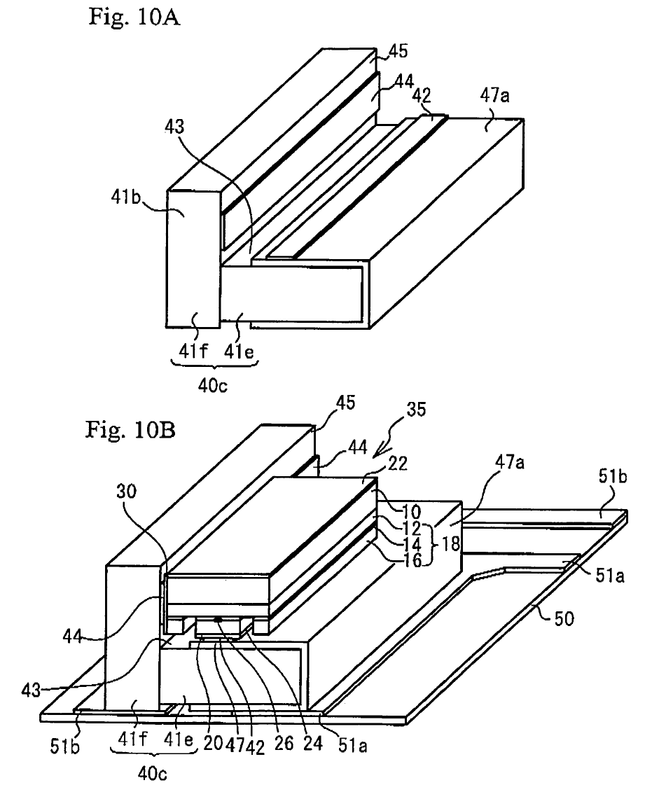

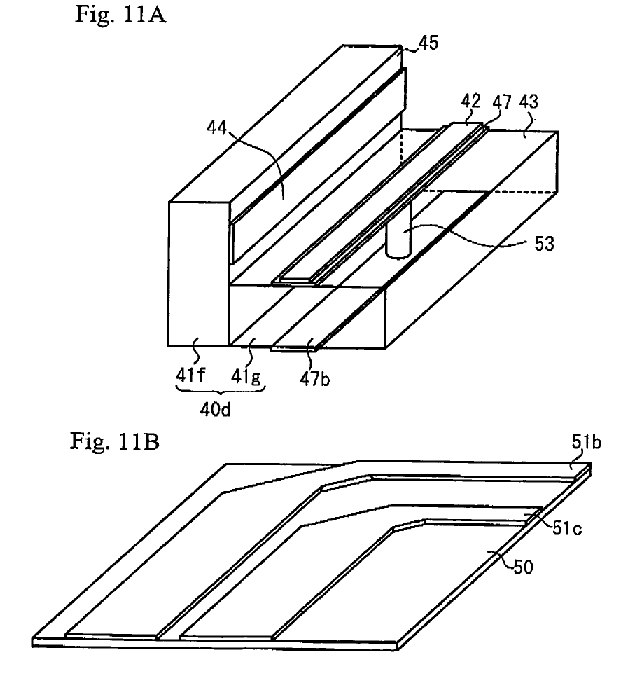

A fourth embodiment is another example of the structure in which a part of the sub-mount is electrically conductive. FIG. 10A is a perspective view of a sub-mount in accordance with the fourth embodiment. Referring to FIG. 10A, a sub-mount 40c has a base 41e made of an insulating material such as ceramic, and a protrusion 41f made of an electrically conductive material such as copper. An electrode 47a is provided on the base 41e so as to extend from the upper surface (first joining face 43) to the lower surface. The brazing material 44 is directly provided on the protrusion 41f. FIG. 10B is a perspective view of an optical semiconductor device in accordance with the fourth embodiment. The sub-mount 40c is mounted on the substrate 50, and the semiconductor laser chip 35 is mounted on the sub-mount 40c. Thus, the first electrode 20 is electrically connected to an interconnection line 51a provided on the substrate 50 via the electrode 47a. The second electrode 30 is connected to an interconnection line 51b provided on the substrate 50 via the protrusion 41f. The remaining structure of the fourth embodiment is the same as shown in FIG. 5.

### Fifth Embodiment

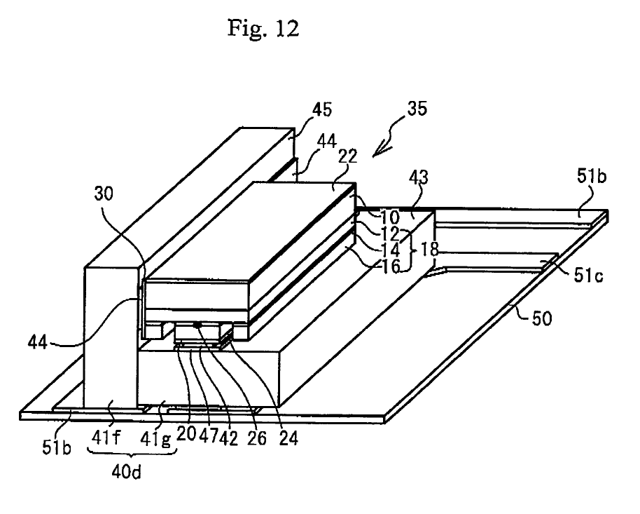

A fifth embodiment has yet another arrangement in which a part of the sub-mount is made of an electrically conductive material. FIG. 11A is a perspective view of a sub-mount in accordance with the fifth embodiment in which the view is seen through a base. A sub-mount 40d has a base 41g made of an insulating material such as ceramic. The electrode 47 is provided on an upper surface of the base 41g, and an electrode 47b is provided on a lower surface thereof. The electrodes 47 and 47b are connected by a via hole 53 that is full of an electrically conductive material such as Au and is penetrated through the base 41g. The sub-mount 40d has the protrusion 41f, which is the same as that of the fourth embodiment shown in FIG. 10A. FIG. 11B is a perspective view of the substrate 50 employed in the fifth embodiment. An interconnection line 51c is formed on the upper surface of the substrate 50 in addition to the above-mentioned interconnection line 51b. FIG. 12 is a perspective view of an optical semiconductor device in accordance with the fifth embodiment. The sub-mount 40d is mounted on the substrate 50, and the semiconductor laser chip 35 is mounted on the sub-mount 40d. Thus, the first electrode 20 is electrically connected to the interconnection line 51c provided on the substrate 50 via the electrode 47 and the via hole 53. The second electrode 30 is connected to the interconnection line 51b provided on the substrate 50 via the protrusion 41f. The remaining structure of the fifth embodiment is the same as that of the first embodiment shown in FIG. 5.

### Sixth Embodiment

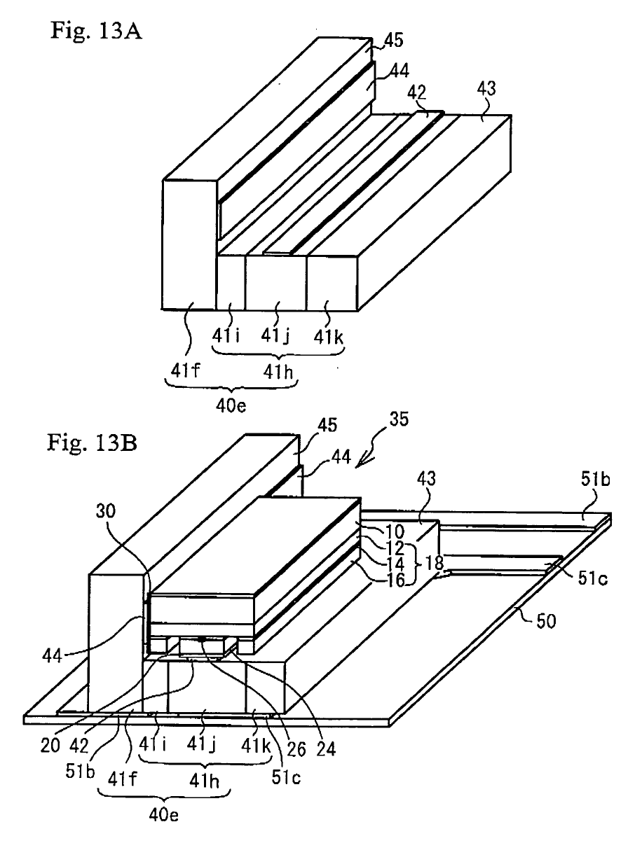

A sixth embodiment has a further arrangement in which a part of the sub-mount is made of an electrically conductive material. FIG. 13A is a perspective view of a sub-mount employed in the sixth embodiment. Referring to FIG. 13A, a sub-mount 40e has a base 41h, which is composed of insulating portions 41i and 41k and an electrically conductive portion 41j. The sub-mount 40e has the protrusion 41f that is the same as that of the fourth embodiment shown in FIG. 10A. FIG. 13B is a perspective view of an optical semiconductor device in accordance with the sixth embodiment. The sub-mount 40e is mounted on the substrate 50, and the semiconductor laser chip 35 is mounted on the sub-mount 40e. Thus, the first electrode 20 is electrically connected to the interconnection line 51c on the substrate 50 via the conductive portion 41j. The second electrode 30 is connected to the interconnection line 51b on the substrate 50 via the protrusion 41f. The remaining structure of the sixth embodiment is the same as that of the first embodiment shown in FIG. 5.

According to the third, fifth and sixth embodiments, a part or all of each of the bases 41c, 41g and 41h (a part of the mounting portion) on which the first joining face 43 is provided may be electrically conductive. As in the case of the fourth through sixth embodiments, a part or all of the protrusion 41f on which the second joining face 45 is provided may be electrically conductive. Thus, a connection from the sub-mount 40 to the substrate 50 can be made without any bonding wire. As in the case of the first and third embodiments, the bonding wire 56 or 58 may be connected to the electrode 47 connected to the first joining face 43 or the electrode 45 (bonding wire region for making an external connection) connected to the second joining face 44.

### Seventh Embodiment

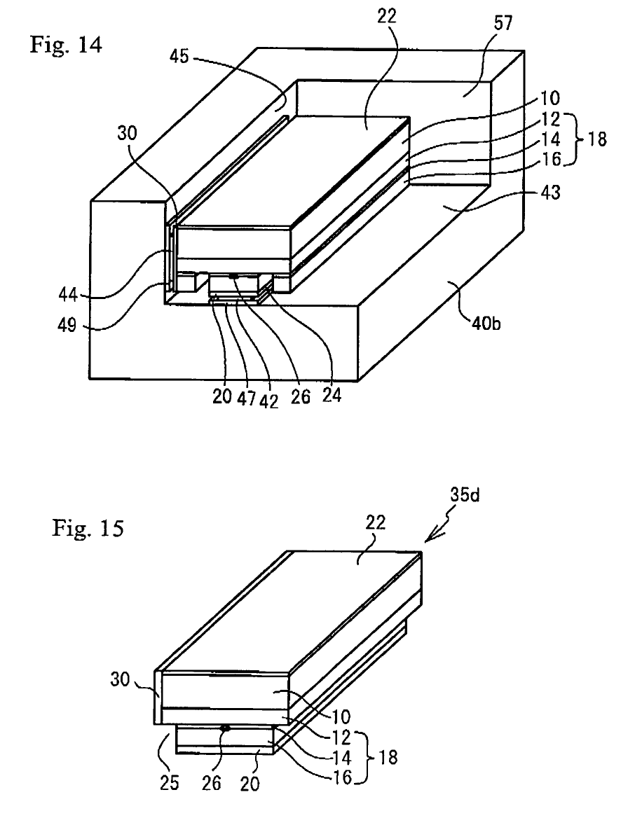

A seventh embodiment has a sub-mount having a different shape. FIG. 14 is a perspective view of an optical semiconductor device in accordance with the seventh embodiment. A sub-mount 40b has a third joining face 57 other than the first joining face 43 and the second joining face 45. In the step in the first embodiment shown in FIG. 3B, the semiconductor laser chip 35 may be brought into contact with not only the second joining face 45 but also the third joining face 57. It is thus possible to improve the precision in positioning of the semiconductor laser chip 35 in not only the lateral direction but also the depth direction.

The sub-mount may be varied so as to have a fourth joining face at a position where the fourth joining face is opposite to the second joining face 45 across the semiconductor laser chip 35. With this structure, the second electrodes provided on the opposite surfaces of the semiconductor laser chip 35 may be joined to at least one of the second joining face 45 and the fourth joining face. It is thus possible to mount the semiconductor laser chip 35 on the sub-mount independent of which one of the side surfaces the second electrode is provided on.

### Eighth Embodiment

An eighth embodiment has a semiconductor laser chip different from the aforementioned semiconductor laser chips. FIG. 15 is a perspective view of a semiconductor laser chip 35d in accordance with the eight eighth embodiment. Referring to FIG. 15, the semiconductor laser chip 35d does not have the grooves 24 used in the first embodiment, and has a mesa structure defined by removing side portions of the first clad layer 16 and the active layer 14. The other structure is the same as that of the first embodiment shown in FIG. 2C. The semiconductor laser chips may be selectively used appropriately. For example, when a connection can be made from an electrode on the main surface of the semiconductor laser chip 35 (on which the operating layer 18 is provided) to the electrode 49 on the sub-mount 40, the semiconductor laser chip 35 may be mounted on the sub-mount 40 so that the back and main surfaces of the chip 35 face down and up, respectively. In this case, the first electrode is provided on the back surface of the semiconductor laser chip. That is, the first electrode may be provided on any of the main and back surfaces of the semiconductor laser chip.

### Ninth Embodiment

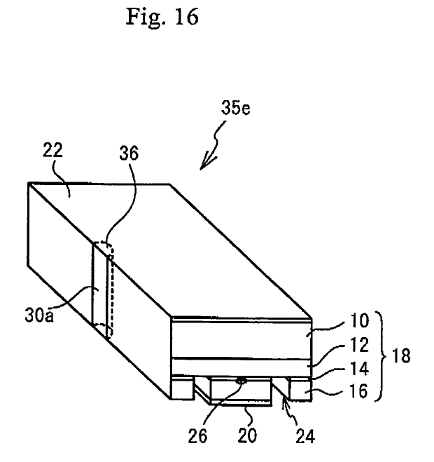

A ninth embodiment has yet another semiconductor laser chip. FIG. 16 is a perspective view of a semiconductor laser chip 35e in accordance with the ninth embodiment. Referring to FIG. 16, a second electrode 30a is provided in a cutoff portion 36 that is provided on a side surface of the semiconductor laser chip 35e and connects the main and back surfaces thereof. The remaining structure of the ninth embodiment is the same as that of the first embodiment shown in FIG. 2C. According to the ninth embodiment, the second electrode 30a is provided in the cutoff portion 36, so that the optical semiconductor device can be downsized. The cutoff portion 36 is not limited to the semi-cylindrical shape but may have a square or rectangular pole or a polygonal pole. The entire cutoff portion 36 may not be full of the second electrode 30a. The second electrode 30a may be provided in a part of the cutoff portion 36 as long as a connection with the electrode 49 can be made.

The first through ninth embodiments are not limited to the aforementioned semiconductor laser chips but may use another type of optical semiconductor chip such as an LED (Light Emitting Diode) or a light-receiving element. Generally, the semiconductor laser chip has a current that flows between the back surface of n-type and the main surface of p-type. Thus, when the semiconductor laser chip 35 is mounted on the sub-mount 40 so that the main surface thereof faces up, the bonding wire must be provided on the back surface of the chip 35, as described in the aforementioned application publication. Thus, the semiconductor laser chip 35 is liable to be damaged. Thus, the present invention is particularly effective for the semiconductor laser chip.

The light-receiving element should be accurately placed in position in order to sense light from an optical fiber at high sensitivity. According to the present invention, such high sensitivity required for the light-receiving element can be realized easily. The mounting portion of the present invention is not limited to the sub-mount but may include any member on which the semiconductor chip is mountable such as a package or a wiring board.

The present invention is not limited to the specifically disclosed embodiments, but may include other embodiments and variations without departing from the scope of the present invention.

The present application is based on Japanese Patent Application No. 2007-030570 filed on Feb. 9, 2007, the entire disclosure of which is hereby incorporated by reference.

What is claimed is:

1. An optical semiconductor device comprising:
a first electrode joined to a first joining face of a mounting portion that is provided in one of a main surface and a back surface of a semiconductor chip; and
a second electrode joined to a second joining face of the mounting portion that is provided in one of the main and back surfaces and a side surface of the semiconductor chip, the second joining face crossing the first joining face.

2. The optical semiconductor device as claimed in claim 1, wherein the second electrode is provided on one of the main and back surfaces of the semiconductor chip and is is located in a region closer to one side edge of the semiconductor chip.

3. The optical semiconductor device as claimed in claim 1, wherein the second electrode is provided on one of the main and back surfaces of the semiconductor chip and a distance between a side surface of the semiconductor chip and a side surface of the second electrode is equal to or less than 3 μm.

4. The optical semiconductor device as claimed in claim 1, wherein the optical semiconductor device is one of a semiconductor laser and a light-receiving element.

5. The optical semiconductor device as claimed in claim 1, wherein the second electrode is provided in a cutoff portion that is provided on a side surface of the semiconductor chip.

6. The optical semiconductor device as claimed in claim 1, wherein the semiconductor chip is flip-chip bonded to the first joining face.

7. An optical semiconductor device comprising:
a semiconductor chip;
a first electrode provided on at least one of a main surface and a back surface of the semiconductor chip;
a second electrode provided on any of the main and back surfaces and a side surface of the semiconductor chip;
a mounting portion on which the semiconductor chip is mounted;
a first joining face which is joined to the first electrode and is provided on the mounting portion; and
a second joining face which is joined to the second electrode and is provided on the side surface of the mounting portion crossing the first joining face.

8. The optical semiconductor device as claimed in claim 7, wherein the second electrode is provided on one of the main and back surfaces of the semiconductor chip and is located in a region closer to one side of the semiconductor chip.

9. The optical semiconductor device as claimed in claim 7, wherein the second electrode is provided on one of the main and back surfaces of the semiconductor chip and a distance between a side surface of the semiconductor chip and a side surface of the second electrode is equal to or less than 3 μm.

10. The optical semiconductor device as claimed in claim 7, wherein the optical semiconductor device is one of a semiconductor laser and a light-receiving element.

11. The optical semiconductor device as claimed in claim 7, wherein the second electrode is provided in a cutoff portion that is provided on a side surface of the semiconductor chip.

12. The optical semiconductor device as claimed in claim 7, further comprising a region that is electrically connected to one of the first joining face and the second joining face and is provided for making an external connection by wire bonding.

13. The optical semiconductor device as claimed in claim 7, wherein the semiconductor chip is flip-chip bonded to the first joining face.

14. The optical semiconductor device as claimed in claim 7, wherein a part of a main body of the mounting portion on which the first joining face is provided by an electrically conductive material.
